(19) United States
(12) Patent Application Publication
(10) Pub. No.: US 2025/0323207 A1
(43) Pub. Date: Oct. 16, 2025

(54) METHOD FOR BONDING ELECTRONICS STRUCTURES DURING INTEGRATED ELECTRONICS MANUFACTURING

(71) Applicant: PulseForge, Inc., Austin, TX (US)

(72) Inventors: Vikram Shreeshail Turkani, Austin, TX (US); Vahid Akhavan Attar, Austin, TX (US); Kurt A. Schroder, Coupland, TX (US); Harry Chou, Austin, TX (US); Ian M. Rawson, Austin, TX (US)

(21) Appl. No.: 19/177,224

(22) Filed: Apr. 11, 2025

Related U.S. Application Data
(60) Provisional application No. 63/632,537, filed on Apr. 11, 2024.

(51) Int. Cl. H01L 23/00

(52) U.S. Cl. CPC H01L 24/80; H01L 24/05; H01L 2224/05647; H01L 2224/80201; H01L 2224/8023; H01L 2224/80379; H01L 2224/80895; H01L 2224/80896

(57) ABSTRACT

Apparatus and associated components and methods for bonding electronics structures. First and second electronics structures are directly bonded using a plurality of light pulses from a flashlamp. In some examples, light from the flashlamp passes into and is absorbed by at least one of the first or second electronics structures to heat a bonding interface between the first and second electronics structures to cause the direct bond to form.

### CROSS-REFERENCE TO RELATED APPLICATIONS

This application claims the benefit of U.S. Provisional Application No. 63/632,537, filed Apr. 11, 2024, which is hereby incorporated herein by reference in its entirety.

### FIELD

The present application relates to electronics manufacturing in general, and, in particular, to a method for bonding electronics structures during integrated electronics manufacturing.

### BACKGROUND

Heterogeneous integration is used in integrated electronics manufacturing processes such as integrated circuit manufacturing. Heterogeneous integration can enhance the performance of integrated circuit devices by combining different materials and technologies onto a single unit (e.g., a chip).

### SUMMARY

In one aspect, a method of forming a composite electronics structure comprises providing a first electronics structure comprising a first electronic component. The first electronic component at least partially defines a bonding face of the first electronics structure. The first electronics structure comprises material capable of absorbing light in a first range of light wavelengths to generate heat. The method includes providing a second electronics structure comprising a second electronic component. The second electronic component at least partially defines a bonding face of the second electronics structure. The first electronics structure is positioned adjacent the second electronics structure such that the bonding face of the first electronics structure abuts the bonding face of the second electronics structure, defining a bonding interface therebetween. The method further includes directly bonding the first electronic component to the second electronic component by using a flashlamp to generate a plurality of flashlamp light pulses and transmitting the plurality of flashlamp light pulses through at least a portion of the first electronics structure toward the bonding interface so that light in the first range of light wavelengths generated by the flashlamp is absorbed by the first electronic component to heat the bonding interface.

Other objects and features will be in part apparent and in part pointed out hereinafter.

### BRIEF DESCRIPTION OF THE DRAWINGS

Aspects of the present disclosure, including various embodiments, further objects, and advantages thereof, will best be understood by reference to the following detailed description when read in conjunction with the accompanying drawings, wherein:

FIGS. 1A-1C illustrate an example of a method for bonding two integrated circuit wafers in wafer-to-wafer hybrid bonding using a pulsed light source, according to a first embodiment;

FIGS. 2A-2C illustrate an example of a method for bonding two chips to an integrated circuit wafer in chip-to-wafer hybrid bonding using a pulsed light source, according to another embodiment;

FIG. 3 illustrates a method for bonding two electronics structures, according to another embodiment;

FIG. 4 illustrates a method for bonding two electronics structures, according to yet another embodiment;

FIG. 5 illustrates a method for bonding two electronics structures, according to a further embodiment;

FIG. 6 illustrates a method for bonding two electronics structures, according to a further embodiment; and

FIGS. 7A-7B illustrate a method for bonding two electronics structures temporarily attached a carrier and subsequently removing the bonded electronics structures from the carrier, according to a further embodiment.

Corresponding reference characters indicate corresponding parts throughout the drawings.

### DETAILED DESCRIPTION

The present disclosure is directed to systems, components, and associated methods for direct permanent bonding of electronics structures such as in integrated circuit manufacturing. It will be appreciated that aspects of the present disclosure can be implemented in other ways without departing from the scope of the present disclosure.

As disclosed herein, a permanent bonding technique for integrated circuit manufacturing and related processes, can be referred to as hybrid bonding. The technique combines a dielectric bond, typically silicon oxide (SiOx), with embedded metal (broadly, “interconnect” or “electronic interconnect”), which can comprise copper or another suitable material, to form interconnections between electronics structures (e.g., wafer-to-wafer, chip-to-wafer, chip-to-panel, etc.). The bonding method can be used for manufacturing of advanced integrated circuits and other varieties of electronic products.

In general, hybrid bonding (broadly, formation of a direct, permanent, and/or face-to-face bond) involves several steps. First, pre-bonding electronics structures (e.g., wafers, chips, panels, light-emitting modules, etc.) are formed by various processes, including dielectric deposition, patterning, etching, copper deposition, and copper CMP, etc. Next, the two electronics structures are brought into contact at room temperature in precise alignment, such that bonding faces of the electronics structures face each other and abut each other at a bonding interface. One or both of the electronics structures are heated to cause a bond to form by material of one or both of the electronics structures diffusing across the bond interface. The heat can be created by irradiating one or both of the electronics structures with incoherent or broadband light, such as from a flashlamp with xenon blub.

Hybrid bonding as referenced herein can include various categories such as wafer-to-wafer (“W2 W”) and chip-to-wafer (“C2 W,” also called die-to-wafer, or “D2 W”). In most cases, the electronics structures will include some type of electronic interconnects desired to be bonded for joining circuitry of the electronics structures. In W2 W bonding, two wafers (broadly, “electronics structures”) having substantially flat bonding faces similar in size and geometry are arranged in a stack and subsequently bonded together to form an integrated composite. In C2 W bonding, one or more smaller electronics structures (e.g., “chips”) are arranged with and bonded to a larger wafer (broadly, “electronics structure”) to form an integrated composite. It will be appreciated that the terms “wafer” and “chip” are used loosely to refer to a wide variety of electronics structures that can be bonded in the above-described configurations. W2 W bonding can accommodate the direct bonding of electronic components (e.g., metal interconnects, dielectric layers) with pitches of up to approximately 0.5 μm, while C2 W bonding can accommodate the direct bonding of electronic components with pitches of up to approximately 1 μm. Generally, the electronic structures in the stack are aligned (broadly, arranged in registration with each other) and brought into physical contact at room temperature, and then they are heated to achieve a permanent, stable bond (e.g., a copper-to-copper bond in the interconnects and an oxide-to-oxide bond in the dielectrics). For example, the bonding of electronic interconnects of the bonded electronics structures can form electronic interconnections between circuitry of the respective electronics structures. Bonding of other portions of the electronics structures can improve structural stability, heat dissipation, insulation, and/or other aspects of the bonded electronics structures.

The present disclosure provides various ways of improving bonding such as hybrid bonding that can be used to enhance the bonding process in heterogeneous integration. Instead of just heating an entire wafer stack via thermal conduction or convection to bond the stack at a global steady-state temperature (e.g., in an oven at 200° C. for at least 3 hours), a light source such as a flashlamp can be used to generate intense light pulses that irradiate and/or transmit into an electronics structure on one side of the stack so that light can be absorbed by the electronics structure to heat the bonding interface between the stacked electronics structures. For example, light can be flashed approximately 100 times over a period of five seconds. This leads to rapid heating and localized melting/plasticizing of the bonding materials at the bonding interface where the electronics devices are engaged in physical contact (e.g., substantially flatwise abutment). While the light is pulsed on and off and absorbed at the bonding interface, heat is conducted away from the bonding interface to the bulk of the electronics structures and supporting components. The flashing process may be repeated multiple times, each time with a high concentration of heat being generated (e.g., at the bonding interface) and dispersed outward. The repeated heating and cooling process allows for rapid heating and annealing in a concentrated area around the bonding interface at relatively high temperatures that are not achievable with steady-state heating systems (such as ovens) due to the temperature sensitivity of other components in the electronics structures.

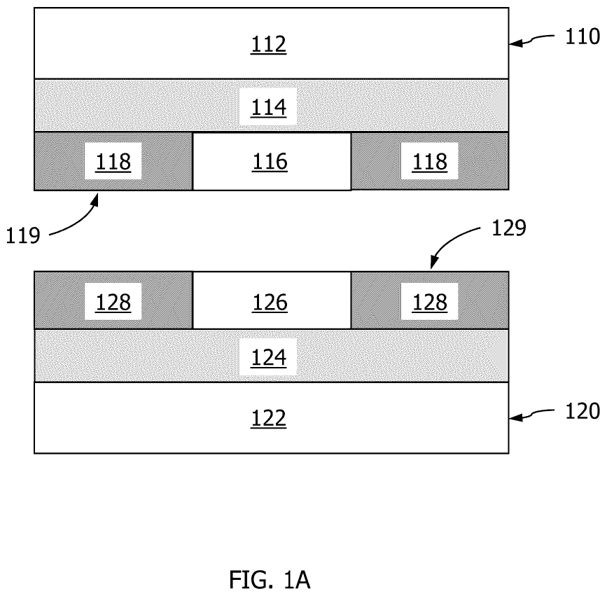

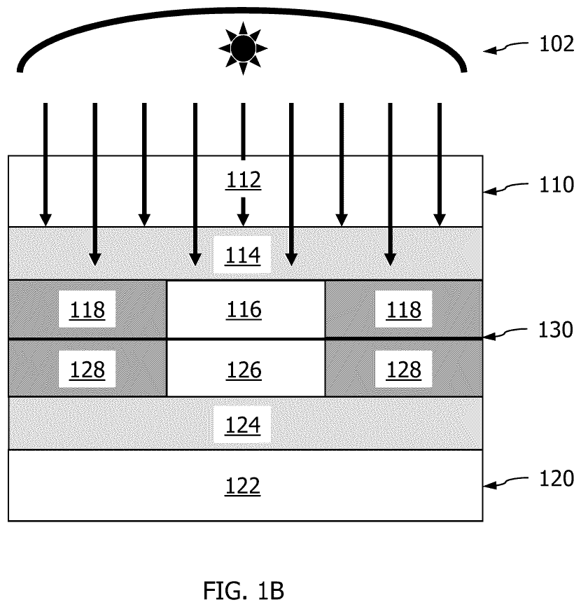

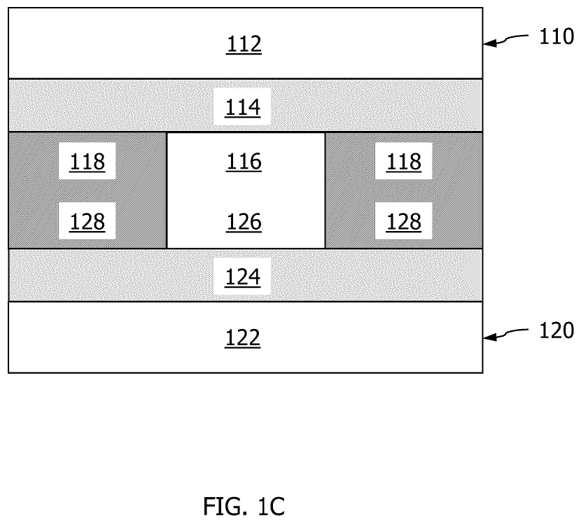

Referring now to the drawings, and more specifically to FIGS. 1A-1C, one example of a W2 W (broadly, electronics-structure-to-electronics structure) hybrid bonding process between two integrated circuit wafers is depicted. In particular, in FIG. 1A, there is depicted a first wafer 110 and a second wafer 120 that are arranged in a stack in accordance with one embodiment. The first wafer 110 includes a first silicon substrate 112, a first back end 114, a first metal interconnect 116 (broadly, an electronic component or electronic interconnect) extending outward from the first back end, and a first dielectric layer 118 surrounding the first metal interconnect. Additionally, the first metal interconnect 116 and first dielectric layer 118 generally at least partially define a first bonding face 119 that faces away from the first silicon substrate 112 and toward that second wafer 120. The second wafer 120 includes a second silicon substrate 122, a second back end 124, a second metal interconnect 126 (broadly, an electronic component or electronic interconnect) extending outward from the second back end, and a second dielectric layer 128 surrounding the second metal interconnect. The second metal interconnect 126 and the second dielectric layer 128 generally at least partially define a second bonding face 129 that faces away from the second silicon substrate 122 and toward the first wafer 110. It will be appreciated that the metal interconnects form part of circuitry of the respective wafers. As depicted in FIG. 1A, the first wafer 110 and the second wafer 120 are substantially identical, but it will be appreciated that other suitable electronics structures can be used instead of either or both of the first wafer and the second wafer. In most circumstances, at least one interconnect from each of the first wafer and the second wafer will be located in registration with each other and then bonded together in accordance with the principles described herein. It will be appreciated that the first wafer 110 and the second wafer 120 can be arranged such that the first bonding face 119 and the second bonding face 129 are in abutting engagement, but the bonding faces are generally not bonded together (other than minor spontaneous bonding that may occur between the first and second dielectric layers 118, 128 at low temperatures). The wafers may be prepared by polishing or planarizing the bonding faces to facilitate abutment of portions of the bonding faces when they are stacked before heating.

Now referring to FIG. 1B, light is pulsed from a light source 102 to heat a bonding interface 130 where the first wafer 110 contacts the second wafer 120 (e.g., where the bonding faces 119 and 129 meet). For example, the light source 102 shown in FIG. 1B comprises a broadband flashlamp (e.g., including one or more bulbs and associated reflector(s)) which can be activated by controlling an IGBT-based switching device so pulses can be controlled on the order of approximately 0.05 to approximately 50 milliseconds. The broadband light emitted by the light source 102 includes light in the near-infrared (or “NIR”) range of light wavelengths. As shown in FIG. 1B, the light source is generally located above the first wafer 110 and emits light in a nominal direction toward the first wafer 110 and the bonding interface 130. It will be appreciated that the first silicon substrate 112 is substantially transmissive to light in the NIR wavelength range, and thus a substantial amount of the light generated by the light source 102 in the NIR wavelength range travels through the first silicon substrate 112, and a substantial amount of this light in the NIR wavelength range is absorbed by the first back end 114, the metal interconnect(s), and or dielectric layer(s) to generate substantial heat near the bonding interface 130. This heating causes material in the first interconnect 116 and the second interconnect 126 to diffuse substantially across the bonding interface 130. Additionally, this heating causes material in the first dielectric layers 118 and respective (e.g., adjoining) second dielectric layers 128 to diffuse substantially across the bonding interface 130. Between pulses of light, heat is permitted to dissipate by diffusing through the bulk of the electronics structures and to supporting structures.

Now referring to FIG. 1C, after the light pulsing cycles are finished, the wafers 110 and 120 are cooled, resulting in direct, permanent, face-to-face bonding therebetween. More specifically, permanent bonds are formed between the first and second interconnects 116, 126 and corresponding pairs of first and second dielectric layers 118, 128.

It is contemplated that the metal interconnects 116, 126 may be copper, any other metal, an alloy, or other suitable material. In some embodiments the metal interconnects 116, 126 may comprise the same material or different materials (e.g., different kinds of metal). Likewise, the dielectric layers 118, 128 may be oxides and may comprise either the same or different materials.

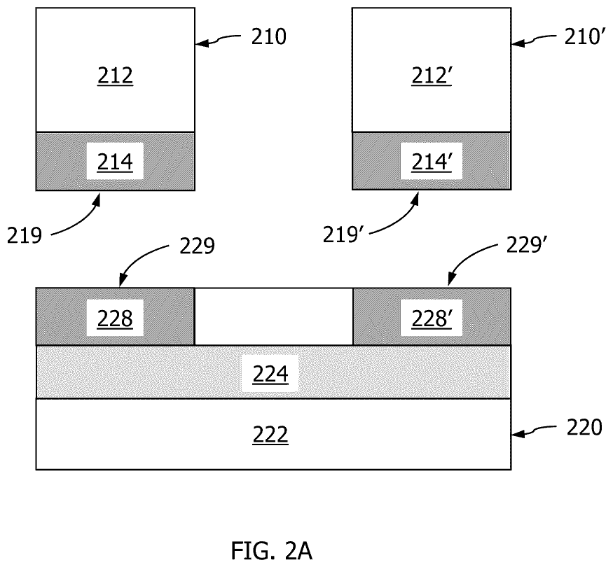

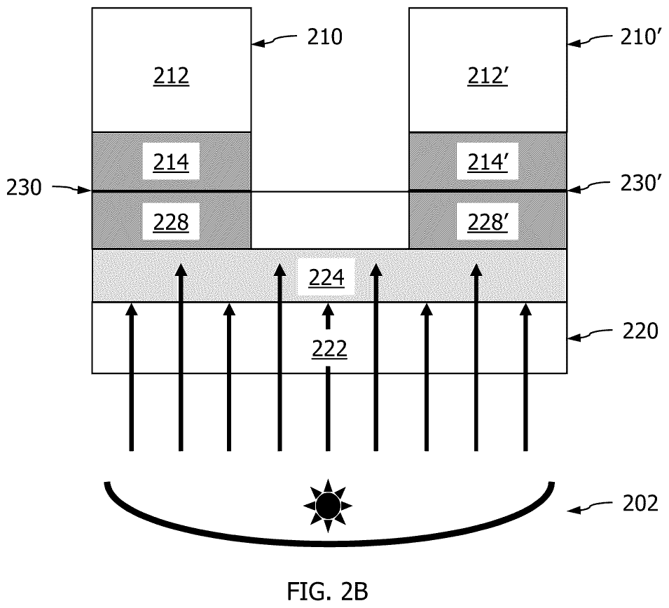

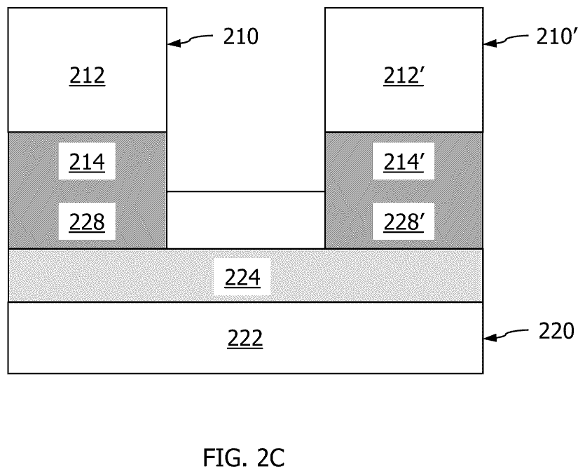

Referring now to FIGS. 2A-2C, an example of a C2 W (broadly, electronics-structure-to-electronics structure) hybrid bonding process between multiple chips and an integrated circuit wafer is depicted. In particular, in FIG. 2A, there is depicted a first chip 210 and a second chip 210′ that are arranged on an integrated circuit wafer 220 to define a stack in accordance with one embodiment. The first chip 210 and second chip 210′ each include a respective first base portion 212, 212′ supporting a respective bonding face portion 214, 214′ defining a respective bonding face 219, 219′. It will be appreciated that the base portions 212, 212′ may comprise substrates (like the substrate 112 discussed above), made of silicon and/or other suitable material, and/or other components suitable for use in electronic chips and can include other components, such as diodes (e.g., light-emitting diodes). Likewise, it will be appreciated that the bonding face portions 214, 214′ can comprise electronic components such as the interconnect 116 and/or other components, such as the dielectric components 118 discussed above. The bonding faces 219, 219′ are each configured to face away from the corresponding base portion 212, 212′ and toward the wafer 220. The wafer 220 includes a silicon substrate 222, a back end 224 supported by the silicon substrate, and first and second bonding face portions 228, 228′ which define respective bonding faces 229, 229′ and are configured to bond with the bonding face portions 214, 214′. The bonding faces 229, 229′ are each configured to face away from the substrate 222 and toward the first and second chips 210, 210′. It will be appreciated that the first and second bonding face portions 228, 228′ may include interconnects and/or dielectric layers as described above in connection with the wafers 110, 120 depicted in FIGS. 1A-1C. The metal interconnects form part of circuitry of the respective wafer(s) and chip(s). It will be appreciated that the first and second chips 210, 210′ can be arranged with the wafer 220 such that the bonding face 219 abuts the bonding face 229 and the bonding face 229′ abuts the bonding face 229′ (with electronic interconnects in registration with each other), but the bonding faces are generally not bonded together (other than minor spontaneous bonding that may occur between dielectric layers at low temperatures). As a preparation step, the bonding faces can be polished or planarized to facilitate the abutment and subsequent bonding.

Now referring to FIG. 2B, light is pulsed from a light source 202 to heat the electronics structures, specifically at the bonding interfaces 230, 230′ where the first and second chips 210, 210′ contact the wafer 220 (e.g., where the bonding faces 219/229 and 219′/229′ meet). For example, the light source 202 shown in FIG. 2B comprises a broadband flashlamp (e.g., including one or more bulbs and associated reflector(s)) which can be activated by controlling an IGBT-based switching device so pulses of incoherent or broadband light can be controlled on the order of approximately 0.05 to approximately 50 milliseconds. The broadband light emitted by the light source 202 includes light in the near-infrared (or “NIR”) range of light wavelengths. As shown in FIG. 2B, the light source 202 is generally located beneath the wafer 220 and emits light in a nominal direction toward the wafer 220 and the bonding interfaces 230, 230′. It will be appreciated that the silicon substrate 222 is substantially transmissive to light in the NIR wavelength range, and thus a substantial amount of the light generated by the light source 202 in the NIR wavelength range travels through the silicon substrate 222. A substantial amount of this light in the NIR wavelength range is absorbed by the back end 224 and/or the bonding face portions to generate substantial heat near the bonding interface 230. This heating causes material in bonding face portion 214 and the bonding face portion 228 to diffuse substantially across the bonding interface 230, and likewise causes material in bonding face portion 214′ and the bonding face portion 228′ to diffuse substantially across the bonding interface 230′.

Now referring to FIG. 2C, after the light is pulsed, the bonded chips 210, 210′ and wafer 220 are instantaneously cooled, and the cycle of rapid heating and cooling is repeated until a permanent, face-to-face bond is formed. Between pulses of light, heat is permitted to dissipate by diffusing through the bulk of the electronics structures and to supporting structures.

It will be appreciated that one or more light sources can be placed on either or both sides of a W2 W stack or a C2 W stack (broadly, electronics structure stack) without departing from the scope of the present disclosure.

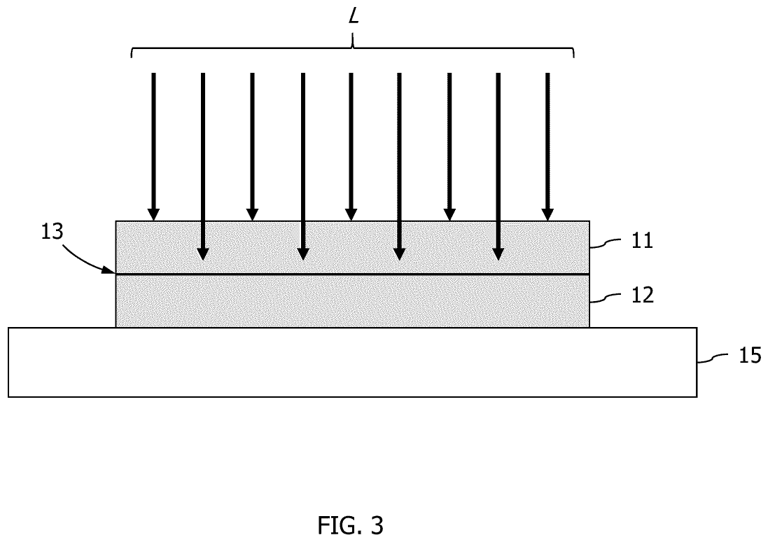

Referring now to FIG. 3, there is depicted a method for bonding two semiconductor wafers (broadly, “electronics structures”). The wafers 11, 12 are shown schematically, and can represent wafers of various complexity, such as wafers 110, 120 of FIGS. 1A-1C. It will be understood the wafers 11, 12 can comprise various features such as substrates, components, layers, etc. In one example, the wafers of FIGS. 1A-1C can be bonded according to the process shown in FIG. 3. As shown, wafers 11 and 12 are placed together initially to form a wafer stack on top of a table 15 (more broadly, a carrier). One or more light pulses L are radiated toward the side of wafer 11. A substantial amount of the pulsed light is absorbed by the wafer 11, such as at or near a bonding interface 13 between wafers 11 and 12. Bonding interface 13 becomes hot, and the heat diffuses from bonding interface 13 to the bulk of wafers 11, 12 and table 15. After a series of pulses, the wafer 11 bonds to the wafer 12, such as in accordance with the principles discussed above.

During processing, one or more carriers, such as the table 15 or any other kind of temporary carrier, may be configured to assist in maintaining a generally constant steady-state temperature while the light is pulsed to prevent the steady-state temperature of non-bonding components in the wafer stack from exceeding a destructive threshold temperature above which the components would sustain damage. For example, the pulsed light temporarily heats the location at the bonding interface to a temperature that is higher than that which could ordinarily be attained in the steady-state, and there is sufficient heat dissipation away from the non-bonding-interface components to minimize exposure to extreme temperatures in other areas more susceptible to damage from exposure to high temperatures, both instantaneously and as a steady state condition is reached. The localized heating described above facilitates inter-diffusion between the materials across the bonding interface, creating a strong bond while also generally minimizing the size of the heat-affected zones. As a result of the localized, regulated heating process described above, the entire bonding process can be completed in a few seconds (instead of hours when steady-state heating solutions are used), thereby enabling higher throughput while also providing better bonds with a reduced overall thermal budget as compared to continuous heating methods at a steady-state temperature. Due to the short duration of the light pulses, the areas closest to the bonding interface are repeatedly heated to comparatively high temperatures suitable for bonding, but the concentration of temperature is limited to a controlled, localized region. Farther away from the bonding interface, the heat dissipates rapidly through the other portions of the wafers. Due to the thermal diffusion characteristics of the wafers and the thermal mass provided by the table (and/or additional heat dissipation provided by optional external cooling sources), thermal equilibrium in the wafers can be achieved after each light pulse, which significantly reduces the risk of exposing the wafers to large-scale thermal stress that can detrimentally affect how the wafers bond together. Accordingly, the bonding process provides a relatively low-stress environment similar to slower, steady-state heating environments, but accomplishes strong, reliable bonding in a fraction of the time with light-emitting and light-absorbing components.

In further applications, holding the table 15 at a predetermined temperature helps to maintain a constant, lower average temperature in the wafers 11, 12 after multiple light pulses are absorbed near the bonding interface and subsequently diffused. Regulating the temperature of the table 15 facilitates heat dissipation away from the bonding interface. It will be appreciated that the intensity, duration, and interval of the light pulses can also be adjusted as additional ways to regulate the instantaneous and steady-state temperature of the wafers 11 and 12 to achieve ideal temperatures near the bonding interface (e.g., sufficiently high to cause the bonding) and away from the bonding interface (e.g., sufficiently low to minimize damage and/or warping).

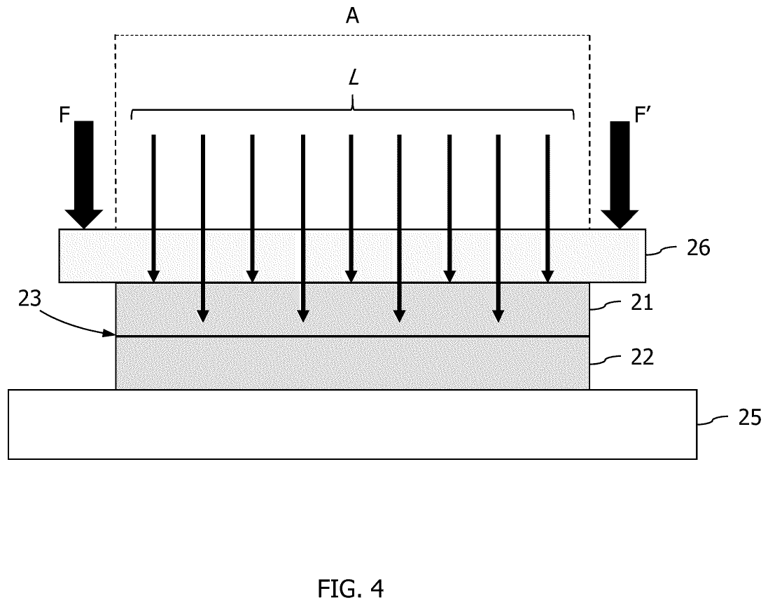

Now referring to FIG. 4, in addition to using light pulses to heat the bonding interface, external pressure can be applied to compress the wafer stack to enhance the bonding process. This may be accomplished with the usage of a reusable backing plate (broadly, pressure member) that is at least partially transparent to light pulses. This allows pressure to be applied while the bonding interface is heated by light pulses. The backing plate may also have a larger area than the wafer stack so that external pressure may be applied at the periphery outboard of the stack while allowing transmission through the backing plate to irradiate the entire wafer stack area. The backing plate can comprise quartz, glass, sapphire, silicon, silicon carbide, and/or other suitable material.

In FIG. 4, there is depicted a method for bonding two semiconductor wafers (broadly, “electronics structures”) with both light and pressure. The wafers 21, 22 are shown schematically, and can represent wafers of various complexity, such as wafers 110, 120 of FIGS. 1A-1C. It will be understood the wafers 21, 22 can comprise various features such as substrates, components, layers, etc. In one example, the wafers of FIGS. 1A-1C can be bonded according to the process shown in FIG. 4. As shown, wafers 21 and 22 are placed together initially to form a wafer stack on top of a table (or carrier) 25. A backing plate 26 (broadly, a pressure member) that is at least partially light transmissive is placed on top of the wafer stack in direct or indirect contact with the wafer 21. External force is applied at the periphery of backing plate 26, as indicated by the reference characters F and F′, while one or more light pulses L are radiated from the side of backing plate 26. The forces F and F′ are generally applied in the same direction as a nominal direction of the pulsed light L. The external force applied to the backing plate 26 creates compression at the bonding interface 23. It will be appreciated that force is applied outboard of the bonding interface and thus outward of an area A through which the light L travels to minimize interference (e.g., avoid obscuring flashlamp light) with the bonding process. It will be appreciated that the weight of the backing plate 26 can provide additional pressure. Some of the light pulses are absorbed at or near a bonding interface 23 between wafers 21, 22. Bonding interface 23 becomes hot, and the heat then diffuses from bonding interface 23 to the bulk of wafers 21, 22 and table 26, with the additional pressure from the external forces F, F′ facilitating the bonding. As described above, the table 26 may be held at a predetermined temperature in order to maintain a constant average temperature if multiple light pulses are utilized.

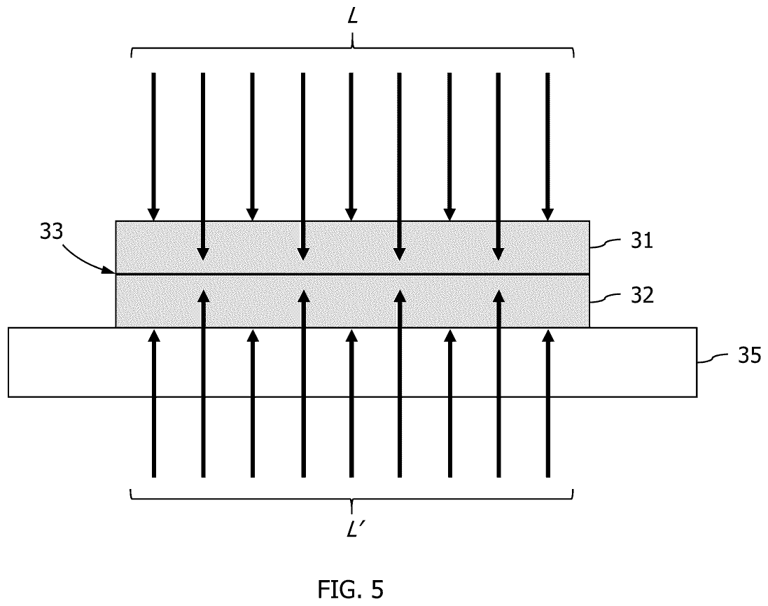

A wafer stack may also be illuminated from both sides, which requires a pulsed light source at both sides of the wafer stack. Referring now to FIG. 5, there is depicted a method for bonding two semiconductor wafers (broadly, “electronics structures”) with two opposing light sources. The wafers 31, 32 are shown schematically, and can represent wafers of various complexity, such as wafers 110, 120 of FIGS. 1A-1C. It will be understood the wafers 31, 32 can comprise various features such as substrates, components, layers, etc. In one example, the wafers of FIGS. 1A-1C can be bonded according to the process shown in FIG. 5. As shown, wafers 31 and 32 are placed together initially to form a wafer stack on top of a table (or carrier) 35. One or more light pulses L are radiated toward the side of wafer 31, and one or more light pulses L′ are radiated toward the side of the wafer 32 from the table 35. Some of the light pulses are absorbed near or at a bonding interface 33 between wafers 31, 32. It will be appreciated that the light pulses L and L′ may comprise light in similar ranges of wavelengths or different ranges of wavelengths. Further, it is contemplated that the wafer 31 may include a light-absorbing material configured to absorb light corresponding to a range of light wavelengths emitted by the one or more light pulses L, while the wafer 32 may include a light-absorbing material configured to absorb light corresponding to a range of light wavelengths emitted by the one or more light pulses L′. The flashlamps on the opposite sides of the stack can cause heat to be generated from both sides of the bonding interface 33. Bonding interface 33 becomes hot, and the heat then diffuses from bonding interface 33 to the bulk of wafers 31, 32 and table 36. As described above, the table 36 may be held at a predetermined temperature in order to maintain a constant average temperature if multiple light pulses are utilized.

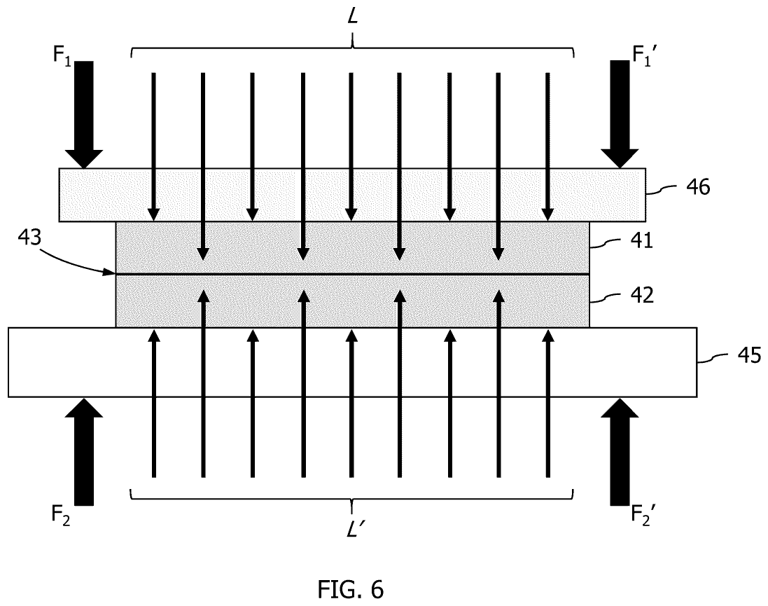

It will be appreciated that light-transmissive carriers or backing plates may be provided on both sides as well. For example, referring now to FIG. 6, there is depicted a method for bonding two semiconductor wafers with two opposing light sources and applied compressive forces. The wafers 41, 42 are shown schematically, and can represent wafers of various complexity, such as wafers 110, 120 of FIGS. 1A-1C. It will be understood the wafers 41, 42 can comprise various features such as substrates, components, layers, etc. In one example, the wafers of FIGS. 1A-1C can be bonded according to the process shown in FIG. 4. As shown, wafers 41 and 42 are placed together initially to form a wafer stack on top of a table (or carrier) 45. A backing plate 46 (broadly, a pressure member) that is at least partially light transmissive is placed on top of the wafer stack in direct or indirect contact with the wafer 41. External force is applied at the periphery of backing plate 46, as indicated by the reference characters F₁ and F₁′, while one or more light pulses L are radiated toward the backing plate 46 and thus the wafer 41. Optionally, additional external force may be applied to the table 45 in an opposing direction, as indicated by the reference characters F₂ and F₂′, while additional light pulses L′ are radiated toward the wafer 42 from the table 45. For example, clamps or other suitable devices can be used to apply the external force F₁, F₁′, F₂, and F₂′. It will be appreciated that the forces F₁ and F₁′ are operative in generally the same direction as a nominal direction of the pulsed light L, while the forces F₂ and F₂′ are operative in generally the same direction as a nominal direction of the pulsed light L′. The external forces applied to the backing plate 46 and/or to the table 45 create compression at the bonding interface 43. In accordance with the phenomena described above, some of the light pulses are absorbed at or near a bonding interface 43 between wafers 41, 42. Bonding interface 43 becomes hot, and the heat then diffuses from bonding interface 43 to the bulk of wafers 41, 42 and table 46, with the additional pressure from the external forces F₁, F₁′, F₂, and F₂′ facilitating the bonding. As described above, the table 45 and/or backing plate 46 may be held at a predetermined temperature in order to maintain a constant average temperature if multiple light pulses are utilized.

The source of light pulses for the above examples can be a flashlamp or a near-infrared (NIR) laser. A flashlamp has emission wavelengths from about 200 nm to 1,500 nm, while an NIR laser operates at a single wavelength. This single wavelength in the NIR region can range between 1,000 nm to 2,000 nm. Most of the light emission from a flashlamp or a NIR laser can pass through a carrier that is made of quartz, glass, or sapphire.

When using a flashlamp, absorption of the light pulses may occur at the surfaces of an electronics device as well as the bonding interface. This is due to the fact that semiconductor materials such as silicon and silicon carbide are partially transparent in the NIR region.

When using a laser or flashlamp, if the area of the light beam is smaller than that of a wafer stack, the source of light may be scanned relative to the wafer stack (and/or wafer stack moved relative to the source of light) to process the entire wafer stack with multiple light pulses. Additionally or alternatively, multiple light sources can be used simultaneously to expand the processing area, such as to cover the entire area to be thermally processed for bonding.

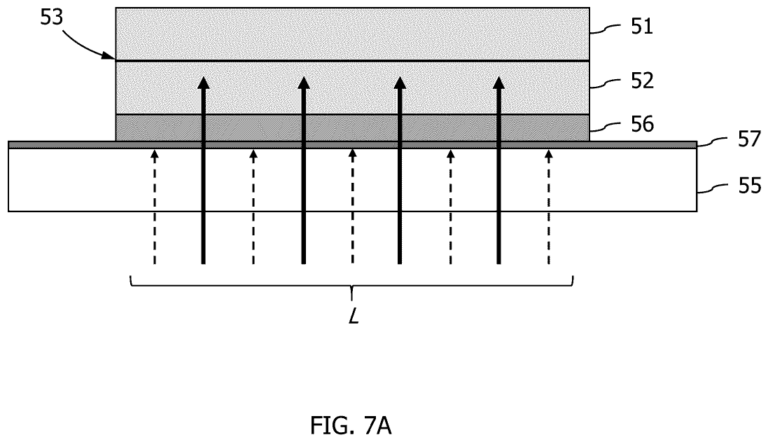

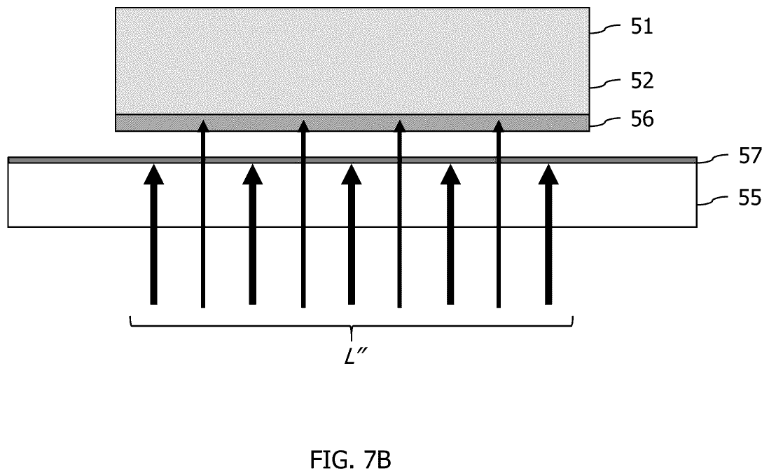

In further aspects, it is contemplated that the above-described hybrid bonding processes can be performed with the assistance of a mobile carrier structure with the assistance of a temporary adhesive, which may be referred to as temporary bonding and debonding. For example, now referring to FIGS. 7A and 7B, there is depicted a method for bonding two semiconductor wafers in a stack including a wafer that is temporarily bonded to a carrier structure. The wafers 51, 52 are shown schematically, and can represent wafers of various complexity, such as wafers 110, 120 of FIGS. 1A-1C. It will be understood the wafers 51, 52 can comprise various features such as substrates, components, layers, etc. In one example, the wafers of FIGS. 1A-1C can be bonded according to the process shown in FIG. 4. As shown in FIG. 7A, the wafer 52 is adhesively bonded to a light-transmissive carrier structure 55 using a temporary adhesive 56. The temporary adhesive 56 includes a material that is substantially transmissive to light (e.g., in a first range of light wavelengths) but can include light-absorbing material that absorbs light (e.g., in a second range of light wavelengths) to generate heat. In addition or alternatively to the adhesive being configured to absorb light, the carrier structure 55 can include a layer of partially-light-transmissive, partially-light-absorptive material as a light-absorbing layer (LAL) 57. It will be appreciated that the presence of light-absorbing material in both the carrier and the adhesive is optional and that either feature could be omitted. Another wafer 51 is placed on the wafer 52 initially to form a wafer stack on top of the carrier structure 55. One or more light pulses L are radiated toward the carrier structure 55, the light pulses L being in the range of light wavelengths that is substantially transmitted through the LAL and/or temporary adhesive 56. A substantial amount of the pulsed light L is absorbed at or near a bonding interface 53 between wafers 51 and 52. Bonding interface 53 becomes hot, and the heat diffuses from bonding interface 53 to the bulk of wafers 51, 52, adhesive 56, and carrier structure 55. After a series of pulses, the wafer 51 bonds to the wafer 52 in accordance with the principles discussed above.

Subsequently, as shown in FIG. 7B, the bonded wafers 51 and 52 are debonded from the carrier structure 55 using one or more intense pulses of light L″ that includes light in a second light wavelength range that is absorbable by the temporary adhesive 56, which are directed through the carrier structure 55 toward the temporary adhesive 56. The light L″ is at least partially absorbed by the temporary adhesive 56, causing the adhesive to heat up and substantially weakening a bonding strength of the adhesive so the bonded wafers 52, 51 can be readily separated from the carrier. Further details regarding suitable equipment and processes for carrier debonding with light-absorbing adhesives and/or light-absorbing carrier layers are provided in U.S. Pat. Nos. 11,358,381 and 11,996,384, respectively, the contents of both hereby being incorporated in their entirety. It will be appreciated that the same broadband flashlamp may be utilized to accomplish both the hybrid bonding (e.g., FIG. 7A) and debonding (e.g., FIG. 7B) by using one or more filters to impede a significant amount of light in the second range of light wavelengths while hybrid bonding is being performed. The filtering of light in the second range of light wavelengths substantially limits the amount of light absorption that occurs in the temporary adhesive while the hybrid bonding process is conducted. Subsequently, the flashlamp can be pulsed without the filter to weaken the bond in the adhesive so the bonded wafers 52, 51 can be removed from the carrier structure 55.

It will be appreciated that the light pulses Z used for bonding the wafers 52, 51 may have a lesser intensity than an intensity of the light pulses L″ used for debonding the wafers from the carrier structure 55. Further, it is understood that a light source (e.g., xenon flash bulb(s)) may be selected (or adapted) based on a characteristic ability of the light source to emit a higher proportion of light in the first range of light wavelengths, for example NIR, at lower intensities (e.g., for bonding the wafers 52, 51), and a higher proportion of light in the second range of light wavelengths, for example ultraviolet, at higher intensities (e.g., for debonding the bonded wafers from the carrier). Thus, in addition to discrete filters, the natural characteristics of light sources can be selected or adapted to facilitate the selective transmission of light in operative wavelength ranges during discrete bonding and debonding stages.

Although the methods discussed above with respect to FIGS. 3-7B are discussed in the context of semiconductor wafers, it will be appreciated that the methods can be used to bond other types of electronics structures, such as chip-to-wafer, chip-to-panel, etc., without departing from the scope of the present disclosure.

It will be appreciated that the processes describe above can be achieved in a variety of settings in electronic manufacturing, including without limitation the manufacture of integrated circuits and display panels.

As has been described, the present disclosure provides methods for directly bonding electronic structure such as semiconductor wafers during integrated circuit manufacturing. This light-assisted hybrid bonding method offers a significant advancement in the field of heterogeneous integration. By leveraging high-intensity light pulses and pressure, this method enables the generation of robust bonds between different materials that are essential for the development of advanced electronic devices. The above-described methods, and variations thereto made apparent from the above examples, enable strong and reliable bonds between different materials in heterogeneous integration, facilitate efficient heat dissipation and electrical connectivity, reduce heat-affected zones, minimize damage to sensitive components, reduce the time to anneal from hours to seconds, and are compatible with existing semiconductor manufacturing processes.

When introducing elements of the present disclosure or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the present disclosure are achieved and other advantageous results attained.

As various changes could be made in the above constructions and methods without departing from the scope of the present disclosure, it is intended that all matter contained in the above description and shown in the accompanying drawings shall be interpreted as illustrative and not in a limiting sense.

### Other Statements of the Disclosure

The following are statements or features of invention described in the present disclosure. Some or all of the following statements may not be currently presented as claims. Nevertheless, the statements are believed to be patentable and may subsequently be presented as claims. Associated methods corresponding to the statements or apparatuses below, and products and apparatuses corresponding to the methods below, are also believed to be patentable and may subsequently be presented as claims. It is understood that the following statements may refer to and be supported by one, more than one, or all the embodiments described above.

A1. A method of forming a composite electronics structure comprising:
providing a first electronics structure comprising a first electronic component, the first electronic component at least partially defining a bonding face of the first electronics structure, wherein the first electronics structure comprises material capable of absorbing light in a first range of light wavelengths to generate heat;
providing a second electronics structure comprising a second electronic component, the second electronic component at least partially defining a bonding face of the second electronics structure;
positioning the first electronics structure adjacent the second electronics structure such that the bonding face of the first electronics structure abuts the bonding face of the second electronics structure, defining a bonding interface therebetween;
applying external force to a pressure member in direct or indirect contact with the first electronics structure to compress the bonding interface, the pressure member comprising material that is at least partially transmissive to light in the first predetermined range of light wavelengths; and
while applying the external force to the pressure member, using a flashlamp to generate a plurality of light pulses that are transmitted through the pressure member and at least a portion of the first electronics structure toward the bonding interface so that light in the first range of light wavelengths generated by the flashlamp is absorbed by the material capable of absorbing light in the first range of light wavelengths to heat the bonding interface to directly bond the first electronics structure to the second electronics structure.

A2. The method of statement A1, wherein the external force is applied to the pressure member in one or more sites located outward of a path of the light generated by the flashlamp.

A3. The method of statement A1, wherein the external force is applied without obscuring a path of the light pulses between the flashlamp and the bonding interface.

B1. A method of forming a composite electronics structure comprising:
providing a bonded stack comprising a carrier, a first electronics structure, and an adhesive temporarily bonding the first electronics structure to the carrier, the first electronics structure comprising a first electronic component, the first electronic component at least partially defining a bonding face of the first electronics structure, wherein the first electronics structure comprises material capable of absorbing light in the NIR wavelength range to generate heat, and wherein the carrier and the adhesive are at least partially transmissive to light in the NIR wavelength range;
providing a second electronics structure comprising a second electronic component at least partially defining a bonding face of the second electronics structure;
positioning the first electronics structure adjacent the second electronics structure such that the bonding face of the first electronics structure abuts the bonding face of the second electronics structure, defining a bonding interface therebetween; and
generating a plurality of light pulses containing light in the NIR wavelength range that are transmitted through the carrier and the adhesive toward the bonding interface so that light in the NIR wavelength range generated by the flashlamp is absorbed by the material capable of absorbing light in the NIR wavelength range to heat the bonding interface to directly bond the first electronic component to the second electronic component.

C1. A method of forming a composite electronics structure comprising:
providing a first electronics structure comprising a first substrate and a first electronic component, the first electronic component comprising a first electronic interconnect at least partially defining a bonding face of the first electronics structure, the substrate comprising a semiconductor that is at least partially transmissive to light in a first range of light wavelengths, the first electronics structure comprising material capable of absorbing light in the first range of light wavelengths to generate heat, the first electronics structure further comprising a first oxide layer at least partially defining the bonding face of the first electronics structure;
providing a second electronics structure comprising a second electronic interconnect at least partially defining a bonding face of the second electronics structure, the second electronics structure comprising a second oxide layer at least partially defining the bonding face of the second electronics structure;
positioning the first electronics structure adjacent the second electronics structure such that the bonding face of the first electronics structure abuts the bonding face of the second electronics structure, defining a bonding interface therebetween; and
using a flashlamp to generate a plurality of light pulses that are transmitted through the first substrate toward the bonding interface so that light in the first range of light wavelengths generated by the flashlamp is absorbed by the first electronic component to heat the bonding interface to directly bond the first electronic interconnect to the second electronic interconnect and directly bond the first oxide layer bonds to the second oxide layer.

D1. A method of forming an integrated circuit comprising:
providing a first electronics structure comprising a first substrate and a first circuitry, the first circuitry comprising a first electronic interconnect at least partially defining a bonding face of the first electronics structure, the substrate comprising a semiconductor that is at least partially transmissive to light in a first range of light wavelengths, the first electronics structure comprising material capable of absorbing light in the first range of light wavelengths to generate heat;
providing a second electronics structure comprising a second substrate and a second circuitry comprising a second electronic interconnect, the second electronic interconnect at least partially defining a bonding face of the second wafer;
positioning the first electronics structure adjacent the second electronics structure such that the bonding face of the first electronics structure abuts the bonding face of the second electronics structure, defining a bonding interface therebetween; and
using a flashlamp to generate a plurality of light pulses that are transmitted through the first substrate toward the bonding interface so that light in the first range of light wavelengths generated by the flashlamp is absorbed by the first electronics structure to heat the bonding interface to directly bond the first electronic interconnect to the second electronic interconnect to form a directly bonded interconnection of the first circuitry to the second circuitry.

E1. A method of forming an electronic display comprising:
providing a display structure comprising a first electronic interconnect at least partially defining a bonding face of the display structure, wherein the display structure comprises material capable of absorbing light in a first range of light wavelengths to generate heat;
providing a light-emitting module comprising a second electronic interconnect at least partially defining a bonding face of the light-emitting module;
positioning the light-emitting module adjacent the display structure such that the bonding face of the light-emitting module abuts the bonding face of the display structure, defining a bonding interface therebetween; and
using a flashlamp to generate a plurality of light pulses that are transmitted through at least a portion of the display structure toward the bonding interface so that light in the first range of light wavelengths generated by the flashlamp is absorbed by the material capable of absorbing light in the predetermined range of light wavelengths to heat the bonding interface to directly bond the first electronic interconnect to the second electronic interconnect.

F1. A method for forming a composite electronics structure, the method comprising:
providing a first electronics structure comprising a first bonding face;
providing a second electronics structure comprising a second bonding face;
arranging the first and second electronics structures to be adjacent to each other with the first bonding face facing and abutting the second bonding face at a bonding interface between the first and second electronics structures;
emitting a plurality of light pulses from a flashlamp to repeatedly irradiate at least one of the first or second electronics structures to heat the bonding interface to form a direct bond of the first electronics structure to the second electronics structure across the bonding interface

F2. The method of statement F1, wherein material of the first bonding face diffuses across the bonding interface to form the direct bond.

F3. The method of statement F1, wherein the first electronics structure comprises a first electronic component at least partially defining the first bonding face, and the second electronics structure comprises a second electronic component at least partially defining the second bonding face, and wherein forming the direct bond comprises directly bonding the first electronic component to the second electronic component.

F4. The method of statement F3, wherein the first electronic component is a first electronic interconnect and the second electronic component is a second electronic interconnect, and wherein forming the direct bond comprises forming a direct bond interconnection of the first electronic interconnect to the second electronic interconnect to connect circuitry of the first electronic structure with circuitry of the second electronic structure.

F5. The method of statement F4, wherein the first electronic structure comprises a first dielectric and the second electronic structure comprises a second dielectric, and wherein the direct bond of the first electronics structure to the second electronics structure comprises a direct bond of the first dielectric to the second dielectric.

F6. The method of statement F1, wherein at least one of the first electronics structure of the second electronics structure is carried by a carrier via temporary adhesive during the emitting of the plurality of light pulses from the flashlamp to form the direct bond, and further comprising removing the carrier from the first electronics structure after forming the direct bond.

F7. The method of statement F1, further comprising transmitting the plurality of light pulses through the carrier to repeatedly irradiate the first electronics structure to heat the bonding interface to form the direct bond.

F8. The method of statement F7, further comprising applying an external force to the carrier to provide compression at the bonding interface while emitting the plurality of light pulses.

F9. The method of statement F1, further comprising applying an external force to a pressure member overlying the first electronics structure to cause compression at the bonding interface while emitting the plurality of light pulses.

F10. The method of statement F9, further comprising transmitting the plurality of light pulses through the pressure member to repeatedly irradiate the first electronics structure to heat the bonding interface to form the direct bond.

F11. The method of statement F1, wherein each pulse of the plurality of light pulses has a pulse duration on the order of microseconds.

What is claimed is:

1. A method of forming a composite electronics structure comprising:
providing a first electronics structure comprising a first electronic component, the first electronic component at least partially defining a bonding face of the first electronics structure, wherein the first electronics structure comprises material capable of absorbing light in a first range of light wavelengths to generate heat;
providing a second electronics structure comprising a second electronic component, the second electronic component at least partially defining a bonding face of the second electronics structure;
positioning the first electronics structure adjacent the second electronics structure such that the bonding face of the first electronics structure abuts the bonding face of the second electronics structure, defining a bonding interface therebetween; and
directly bonding the first electronic component to the second electronic component by using a flashlamp to generate a plurality of flashlamp light pulses and transmitting the plurality of flashlamp light pulses through at least a portion of the first electronics structure toward the bonding interface so that light in the first range of light wavelengths generated by the flashlamp is absorbed by the first electronic component to heat the bonding interface.

2. The method of claim 1, wherein directly bonding the first electronic component to the second electronic component comprises diffusing material from the first electronic component toward the second electronic component across the bonding interface.

3. The method of claim 1, wherein the first electronics structure comprises a first substrate carrying the first electronic component, the first substrate comprising material that is at least partially transmissive to light in the first range of light wavelengths.

4. The method of claim 1, wherein the first electronic component comprises a first electronic interconnect, the second electronic component comprises a second electronic interconnect, and wherein directly bonding the first electronic component to the second electronic component comprises forming a direct bond interconnection between the first electronic interconnect and the second electronic interconnect.

5. The method of claim 4, wherein the first electronic interconnect comprises a first metal.

6. The method of claim 5, wherein the first metal is copper.

7. The method of claim 5, wherein the second electronic interconnect comprises a second metal and the second electronic interconnect does not include the first metal.

8. The method of claim 4:
wherein the first electronics structure further comprises a first dielectric component and the second electronics structure further comprises a second dielectric component; and
further comprising directly bonding the first dielectric component to the second dielectric component.

9. The method of claim 8, wherein directly bonding the first dielectric component to the second dielectric component comprises heating at least one of the first dielectric component or the second dielectric component via the plurality of flashlamp light pulses.

10. The method of claim 9, wherein the first dielectric component comprises an oxide and the second dielectric component comprises an oxide.

11. The method of claim 1, wherein the plurality of flashlamp light pulses comprise broadband light including light in the first range of light wavelengths.

12. The method of claim 11, wherein the first range of light wavelengths comprises wavelengths in the NIR spectrum.

13. The method of claim 1, further comprising:
before directly bonding the first electronic component to the second electronic component, temporarily bonding the first electronics structure to a carrier structure using a temporary adhesive, the carrier structure being at least partially transmissive to light in the first range of light wavelengths;
transmitting a plurality of flashlamp light pulses through the carrier structure for transmitting the plurality of flashlamp light pulses through the at least a portion of the first electronics structure toward the bonding interface; and
after directly bonding the first electronic component to the second electronic component, photonically debonding the first electronics structure from the carrier by generating a second plurality of flashlamp light pulses to weaken the temporary adhesive.

14. The method of claim 13, further comprising:
while using the flashlamp to generate the plurality of flashlamp light pulses, filtering light having wavelengths in a range of debonding light wavelengths from the plurality of flashlamp light pulses to prevent the light having wavelengths in the range of debonding light wavelengths from irradiating the temporary adhesive, the filtered light having wavelengths in the range of debonding light wavelengths being outside the first range of light wavelengths; and
while photonically debonding the first electronics structure from the carrier:
not filtering the light having wavelengths in the range of debonding light wavelengths from the second plurality of light pulses; and
absorbing the light having wavelengths in the range of debonding light wavelengths to generate heat to weaken the adhesive.

15. The method of claim 1, further comprising, while using the flashlamp to generate the plurality of flashlamp light pulses, applying a force on at least one of the first electronics structure or the second electronics structure to provide compression at the bonding interface.

16. The method of claim 15, wherein applying the force comprises applying an external force to a pressure member between the flashlamp and the bonding interface.

17. The method of claim 16, wherein the pressure member is transmissive of the first range of light wavelengths, and wherein the external force is applied without obscuring a path of the light pulses between the flashlamp and the bonding interface.

18. The method of claim 16, wherein the flashlamp is a first flashlamp and the plurality of flashlamp light pulses are directed in generally the first direction toward the bonding interface, and wherein the second electronics structure comprises material capable of absorbing light in a second range of light wavelengths to generate heat, the method further comprising:
using a second flashlamp to generate a second plurality of flashlamp light pulses in including light in the second predetermined range of light wavelengths, the second plurality of light pulses being directed toward the bonding interface in a nominal the second direction toward the bonding interface to generate additional heat at the bonding interface, the nominal second direction being generally opposite the first direction.

19. The method of claim 18, wherein the second range of light wavelengths is different from the first range of light wavelengths.

20. The method of claim 1, wherein the flashlamp is a first flashlamp and the plurality of flashlamp light pulses are directed from the first flashlamp toward the bonding interface in a first nominal direction, the method further comprising using a second flashlamp to generate second plurality of flashlamp light pulses including light in a second range of light wavelengths, wherein the second plurality of light pulses are directed from the second flashlamp toward the bonding interface in a second nominal direction generally opposite the first nominal direction to generate additional heat at the bonding interface for directly bonding the first electronic component to the second electronic component.

21. The method of claim 1, further comprising carrying one of the first electronics structure or the second electronics structure on a carrier configured to dissipate heat from the bonding interface, wherein the step of using the flashlamp to generate the plurality of light pulses further comprises simultaneously using the carrier to transfer heat away from the carried one of the first electronics structure or the second electronics structure.

22. The method of claim 1, further comprising permitting heat to dissipate from the bonding interface between pulses of the plurality of flashlamp light pulses to maintain an average temperature of the first electronics structure below a destructive threshold temperature.
